(19) United States
(12) Patent Application Publication
(10) Pub. No.: US 2010/0207673 A1
(43) Pub. Date: Aug. 19, 2010

(54) ASYMMETRIC CHARGE PUMP AND PHASE LOCKED LOOPS HAVING THE SAME

(76) Inventors: Young-Sik KIM, Gunpo-si (KR); Youngsoo Sohn, Gunpo-si (KR); Seungjun Bae, Hwaseong-si (KR); Sanghyup Kwak, Seoul (KR)

Correspondence Address: F. CHAU & ASSOCIATES, LLC, 130 WOODBURY ROAD, WOODBURY, NY, 11797, US

(21) Appl. No.: 12/686,668

(22) Filed: Jan. 13, 2010

(30) Foreign Application Priority Data
Feb. 19, 2009 (KR) 10-2009-0014041

(51) Int. Cl. H03L 7/06; G05F 1/10

(52) U.S. Cl. 327/157; 327/536

(57) ABSTRACT

A charge pump includes a current source configured to generate a first current and a switch circuit including an output node and connected to the current source. The switch circuit is configured to be switched to provide one of the first current to the output node or discharge a second current from the output node according to a phase difference between a reference signal and a feedback signal. The switch circuit is further configured to compare a charge supplied to the output node and a charge discharged from the output node and to adjust an inflow time of the first current to the output node or an outflow time of the second current from the output node according to the comparison result.

### CROSS-REFERENCE TO RELATED APPLICATIONS

This application claims priority under 35 U.S.C §119 to Korean Patent Application No. 10-2009-0014041, filed on Feb. 19, 2009, the disclosure of which is incorporated by reference herein.

### BACKGROUND

1. Technical Field

Embodiments of the present invention relate to an asymmetric charge pump and a phase locked loop (PLL) including the same.

2. Discussion of Related Art

A communications system using digital data can use a phase locked loop (PLL) or a delay locked loop (DLL) for signal synchronization to transfer the data reliably at high speeds. The PLL may include a phase frequency detector (PFD), a charge pump, a loop filter, a voltage controlled oscillator (VCO), and a divider. The phase frequency detector compares a phase of a feedback VCO signal with a phase of a reference signal to output up and down signals. The up and down signals are provided to the VCO via the charge pump and the loop filter to be used as voltage control signals for controlling the VCO.

The phase frequency detector may be a dynamic logic PFD or a complementary logic PFD. Since the dynamic logic PFD is sensitive to skew with respect to an input signal and consumes a large amount of power, a circuit designer may decide to use the complementary logic PFD.

The complementary logic PFD detects a difference between phases of a reference signal and a feedback signal to output differential signals to a charge pump. For example, the complementary logic PFD outputs an up signal, an inverted version of the up signal (e.g., an up-bar signal), a down signal, and an inverted version of the down signal (e.g., a down-bar signal). However, the complementary logic PFD requires a charge pump that can interface with the differential signals (e.g., a differential charge pump).

A differential charge pump should satisfy first and second locking conditions. The first locking condition is satisfied when an amount of charged charge becomes identical to the amount of discharged charge. The second locking condition is satisfied when up current flowing through an up current source becomes identical to the amount flowing through a down current source.

If the first locking condition is satisfied, a control voltage is constantly maintained because the amount of charged charge becomes identical to that of discharged charge and the phase locked loop is said to be locked. If the second locking condition is satisfied, lock skew arises because inflow time of up current is different from outflow time of down current.

In a differential charge pump, up and down currents vary according to a control voltage due to channel-length modulation. For example, a control voltage increases as frequency is increased, which reduces up current and increases down current. Accordingly, the inflow time of the up current is increased and the outflow time of the down current is reduced, thereby resulting in lock skew.

Alternately, the control voltage is reduced as frequency decreases, which increases up current and reduces down current. Accordingly, the inflow time of the up current is reduced and the outflow time of the down current is increased, thereby resulting in lock skew.

Thus, there is a need for a charge pump and a PLL including the charge pump that can reduce or eliminate lock skew.

### SUMMARY

A charge pump according to an exemplary embodiment of inventive concept includes a current source configured to generate a first current and a switch circuit including an output node, connected to the current source, and configured to be switched to provide one of the first current to the output node or discharge a second current from the output node according to a phase difference between a reference signal and a feedback signal. The switch circuit is further configured to compare a charge supplied to the output node and a charge discharged from the output node and to adjust an inflow time of the first current to the output node or an outflow time of the second current from the output node according to the comparison result.

A charge pump according to an exemplary embodiment of inventive concept includes a first current source connected between a power supply voltage and a first node and configured to generate a first current, a first switch connected between the first node and a second node and configured to operate in response to a first signal generated according to a phase difference between a reference signal and a feedback signal, a second current source connected between a ground voltage and a third node and configured to generate a second current, and a second switch connected between the second node and the third node and to operate in response to a second signal generated according to a phase difference between the reference signal and the feedback signal. The first and second switches are configured to compare a charge supplied to the output node and a charge discharged from the output node and to adjust one of an inflow time of a current flowing to the output node or an outflow time of a current flowing from the output node according to the comparison result.

A phase locked loop according to an exemplary embodiment of inventive concept includes a phase detector configured to detect a phase difference between a reference signal and an output signal and to generate a first signal and a second signal according to the detection result, a charge pump configured to supply a first current to an output node in response to the first signal and to discharge a second current from the output node in response to the second signal, a loop filter connected to the output node and configured to generate a control voltage according to one of the first current or the second current and to maintain the control voltage, and a voltage controlled oscillator configured to generate the output signal having a frequency corresponding to the control voltage. The charge pump is configured to control one of an inflow time of the first current to the loop filter or an outflow time of the second current from the loop filter when the control voltage is maintained constantly.

### BRIEF DESCRIPTION OF THE FIGURES

Exemplary embodiments of the present invention will become more apparent from the following description with reference to the following figures, wherein like reference numerals refer to like parts throughout the various figures unless otherwise specified, and wherein

FIG. 1 is a block diagram of a phase locked loop according to an exemplary embodiment of the inventive concept;

FIG. 2 is a circuit diagram of an asymmetric charge pump according to an exemplary embodiment of the inventive concept;

FIG. 3 is a timing diagram to aid in describing how lock skew may be reduced by the asymmetric charge pump illustrated in FIG. 2;

FIG. 4 is a circuit diagram of an asymmetric charge pump according to an exemplary embodiment of the inventive concept;

FIG. 5 is a timing diagram to aid in describing how lock skew may be reduced by the asymmetric charge pump illustrated in FIG. 4; and

FIG. 6 is a diagram for comparing lock skews of a phase locked loop according to an exemplary embodiment of the inventive concept and a conventional phase locked loop.

### DETAILED DESCRIPTION OF EXEMPLARY EMBODIMENTS

Hereinafter, exemplary embodiments of the invention will be described in detail with reference to the accompanying drawings. The inventive concept may however be embodied in different forms and should not be construed as limited to the exemplary embodiments set forth herein.

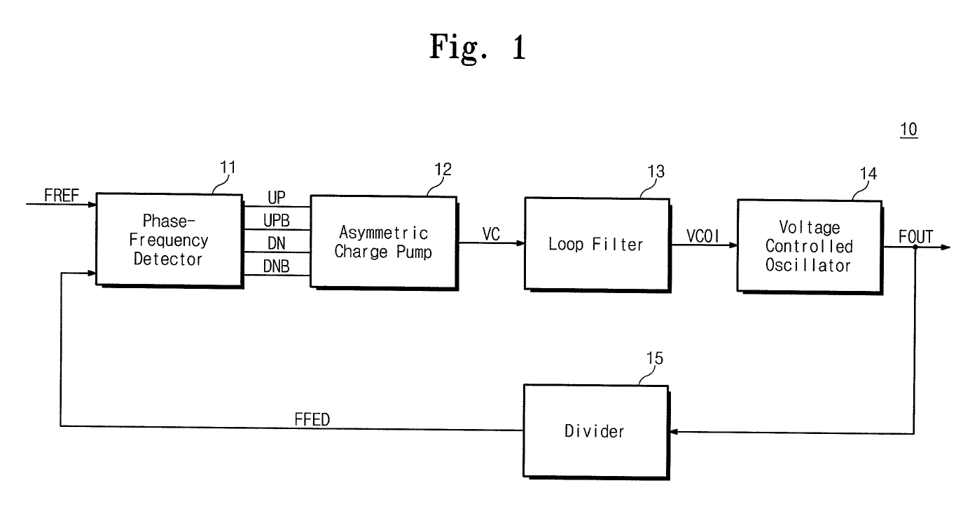

FIG. 1 is a block diagram of a phase locked loop according to an exemplary embodiment of the inventive concept. Referring to FIG. 1, a phase locked loop (PLL) 10 may include a phase frequency detector (PFD) 11, an asymmetric charge pump 12, a loop filter 13, a voltage controlled oscillator 14, and a divider 15. The asymmetric charge pump 12 according to an embodiment of the inventive concept may be configured to adjust/control inflow time of up current and outflow time of down current. The phase frequency detector 11 may be a complementary logic PFD. However; the phase frequency detector is not limited to the complementary logic PFD.

The PLL 10 receives a reference signal FREF having a reference frequency to generate an output signal FOUT having a frequency M-times (M being an integer) higher than the reference frequency.

The PFD 11 may detect a phase difference between the reference signal FREF and the output signal FOUT to generate an up signal UP, an inverted version of the up signal (e.g., an up-bar signal UPB), a down signal DN, and an inverted version of the down signal (e.g., an down-bar signal DNB), The asymmetric charge pump 12 may be configured to supply current to the loop filter 13 or discharge current from the loop filter 13 in response to the signals UP, UPB, DN, and DNB from the PFD 11. The asymmetric charge pump 12 may convert the signals UP, UPB, DN, and DNB (e.g., pulse signals) into corresponding current and provide the converted current to the loop filter 13. An output voltage VC of the asymmetric charge pump 12 may be provided to the loop filter 13.

The asymmetric charge pump 12 may be configured such that a switch operation performed in response to the up signal UP is asymmetric to a switch operation performed in response to the up-bar signal UPB and such that a switch operation performed in response to the down signal DN is asymmetric to a switch operation performed in response to the down-bar signal DNB. The asymmetric switch operation is not a symmetric switch operation. For example, a symmetric switch operation indicates that while a switch operation is turned on according to the up signal UP, it is turned off according to the up-bar signal UPB. Alternately, the asymmetric switch operation indicates that while a switch operation is turned on according to the up signal UP, it is not turned off according to the up-bar signal UPB.

The asymmetric charge pump 12 may be configured to control the inflow time of the up current to the loop filter 13 and the outflow time of the down current from the loop filter 13 according to the asymmetric switch operation, thereby enabling lock skew to be reduced.

The loop filter 13 may be configured to generate a control voltage VCOI to be provided to the VCO 14 according to inflow or outflow current and to maintain the control voltage VCOI constantly. The PLL is considered locked when the control voltage VCOI is constantly maintained. The loop filter 13 may be a low pass filter. The low pass filter may perform roles of filtering various noises generated at a loop operation and vary the control voltage VCOI via a variation of an amount of charge accumulated using a capacitor.

The VCO 14 may be configured to generate the output signal FOUT having a frequency which is proportional to the input control voltage VCOI. The divider 15 may be configured to divide a frequency of the output signal FOUT by 1/M (e.g., where M is an integer) to generate a divided feedback signal FFED, which may be applied to the PFD 11. The PLL 10 may reduce lock skew due to a phase difference between the reference signal FREF and the feedback signal FFED.

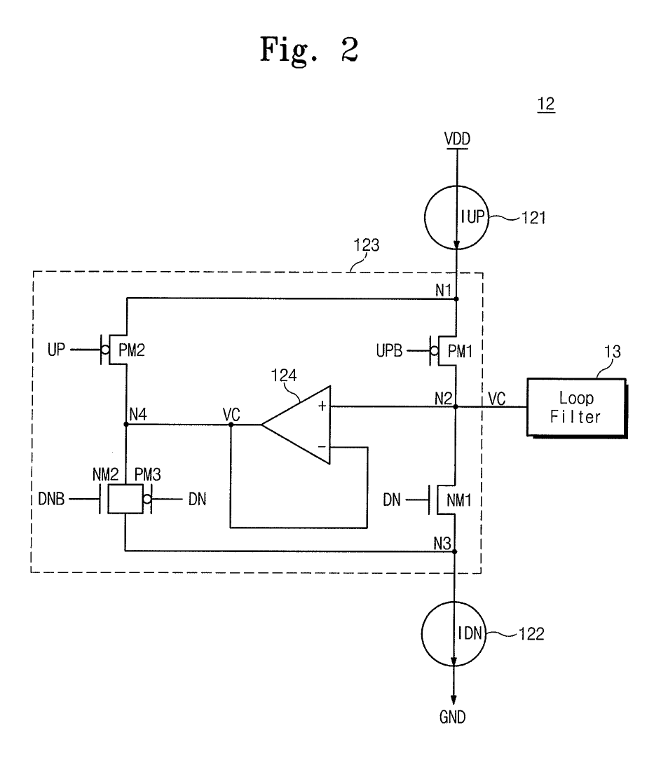

FIG. 2 is a circuit diagram showing an asymmetric charge pump according to an exemplary embodiment of the inventive concept. Referring to FIG. 2, an asymmetric charge pump 12 may include an up current source 121, a down current source 122, and a switch circuit 123. The switch circuit 123 may be configured to perform an asymmetric switch operation in response to down and down-bar signals DN and DNB.

The up current source 121 is connected between a power supply voltage VDD and the first node N1, and supplies up current IUP to a loop filter 13 when the switch circuit 123 performs a switch operation in response to the signals UP and UPB. An output voltage VC may be provided to the loop filter 13 via the second node N2, which is an output node of the asymmetric charge pump 12.

The down current source 122 is connected between a third node N3 and a ground voltage GND, and discharges down current IDN from the loop filter 13 connected to the second node N2 when the switch circuit 123 performs a switch operation in response to the signals DN and DNB. The switch circuit 123 may include the first PMOS transistor PM1, the second

PMOS transistor PM2, the third PMOS transistor PM3, the first NMOS transistor NM1, the second NMOS transistor NM2, and an amplifier 124.

The first PMOS transistor PM1 has a source connected to the first node N1, a drain connected to the second node N2, and a gate connected to receive the up-bar signal UPB. The first PMOS transistor PM1 connects the first and second nodes N1 and N2 to one another in response to the up-bar signal UPB. For example, the first PMOS transistor PM1 may provide the up current IUP from the up current source 121 to the loop filter 13 connected to the second node N2 in response to the up-bar signal UPB.

The second PMOS transistor PM2 has a source connected to the first node N1, a drain connected to a fourth node N4, and a gate connected to receive the up signal UP.

The fourth node N4 is an output node of the amplifier 124. The second PMOS transistor PM2 connects the first and fourth nodes N1 and N4 to one another in response to the up signal UP.

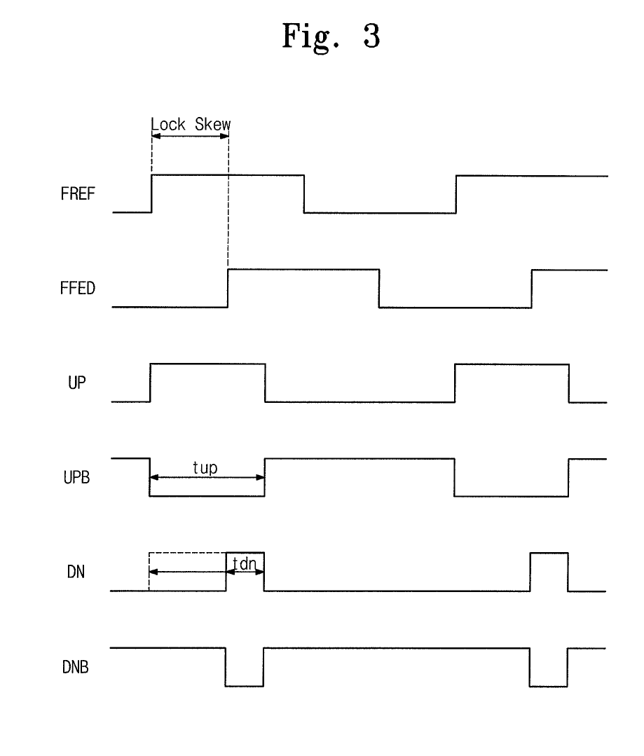

The third PMOS transistor PM3 has a source connected to the fourth node N4, a drain connected to the third node N3, and a gate connected to receive the down signal DN. The third PMOS transistor PM3 connects the third and fourth nodes N3 and N4 to one another in response to the down signal DN. The third PMOS transistor PM3 may be configured to adjust a voltage of the third node N3 to reduce the lock skew of the PLL 10, which will be more fully described with reference to FIG. 3.

The first NMOS transistor NM1 has a drain connected to the second node N2, a source connected to the third node N3, and a gate connected to receive the down signal DN. The first NMOS transistor NM1 connects the second node N2 and N3 to one another in response to the down signal DN. For example, the first NMOS transistor NM1 may be configured to discharge the down current IDN of the down current source 122 from the loop filter 13 connected to the second node N2 in response to the down signal DN.

The second NMOS transistor NM2 has a drain connected to the fourth node N4, a source connected to the third node N3, and a gate connected to receive the down-bar signal DNB. The second NMOS transistor NM2 connects the third and fourth nodes N3 and N4 to one another in response to the down-bar signal DNB.

The amplifier 124 has a positive input terminal connected to the second node N2, a negative input terminal connected to the fourth node N4, and an output terminal connected to the fourth node N4 and its negative input terminal. The amplifier 124 may be used as a voltage follower which transfers the output voltage VC of the asymmetric charge pump 12 to the fourth node N4. The voltage follower may be an amplifier whose gain is 1.

The switch circuit 123 may be configured such that a voltage of the third node N3 is maintained at the output voltage VC when the first NMOS transistor NM1 is turned off.

Although the transistors PM1 and NM1 forming main paths of the up and down currents IUP and IDN may be turned off, the transistors PM2 and NM2 may be used to enable constant current to flow via the sources 121 and 122. For example, the transistors PM2 and NM2 may be used as a sub path for removing switching noises.

FIG. 3 is a timing diagram for describing how lock skew may be reduced by an asymmetric charge pump illustrated in FIG. 2. For ease of description, it is assumed that PLL 10 satisfies the first locking condition. The first locking condition is satisfied when an amount of charge (e.g., Qup(t)) charged to a loop filter 13 by an asymmetric charge pump 12 becomes identical to the amount of charge (e.g., Qdn(t)) discharged from the loop filter 13. For example, the first locking condition may be satisfied by the following conditions: Qup(t)=IUP*tup, Qdn(t)=IDN*tdn, and IUP*tup=IDN*tdn.

Herein, a time tup indicates inflow time of up current to the loop filter 13 as a turn-on time of the first PMOS transistor PM1 in a switch circuit 123, and a time tdn indicates outflow time of up current from the loop filter 13 as a turn-on time of the first NMOS transistor NM1 in the switch circuit 123.

As illustrated in FIG. 3, the signals FREF and FFED satisfy the first locking condition and do not satisfy the second locking condition. For example, although a frequency of the feedback signal FFED is identical or substantially identical to that of the reference signal FREF, lock skew arises because the time tup is longer than the time tdn. However, the lock skew may be reduced by increasing the time tdn.

The time tdn may be increased by an asymmetric charge pump 12 according to an exemplary embodiment of the inventive concept. Since the first locking condition is satisfied and the time tup is longer than the time tdn, an inflow amount of up current IUP is greater than an outflow amount of down current IDN. The time tdn may be increased by reducing an actual outflow time of the down current IDN. For example, the actual outflow time of the down current IDN may be reduced by maintaining a voltage of the third node N3 at an output voltage VC when the first NMOS transistor NM1 is turned off.

When the first NMOS transistor NM1 is turned off, the third node N3 is set to the output voltage VC. Accordingly, although a turn-on voltage is applied to a gate of the first NMOS transistor NM1, its actual turn-on operation may be performed when a voltage of the third node N3 is below a voltage of VDD-Vth1 (e.g., Vth1 is a threshold voltage of transistor NM1).

If the output voltage VC is less than the voltage (VDD-Vth1), the first NMOS transistor NM1 is turned on without delay. Alternately, if the output voltage VC is greater than the voltage (VDD-Vth1), the first NMOS transistor NM1 is maintained at a turn-off state until a voltage of the third node N3 is dropped below the voltage (VDD-Vth1).

As the output voltage VC increases according to a frequency, an actual turn-on time of the first NMOS transistor NM1 may decrease, which reduces the down current IDN discharged from the loop filter 13. At this time, since the PLL 10 satisfies the first locking condition, the time tdn may increase and a difference between the times tup and tdn may be reduced. As a result, the lock skew may decrease.

The asymmetric charge pump 12 may be used to control a voltage controlled oscillator operating at a high frequency as the output voltage VC increases. However, the voltage controlled oscillator is not limited thereto. For example, the asymmetric charge pump 12 may be used to control a voltage controlled oscillator operating at a high frequency as the output voltage VC decreases.

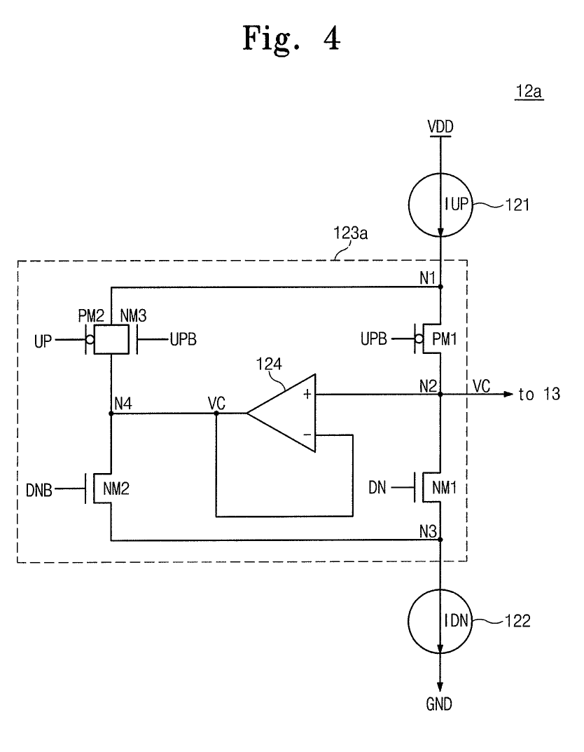

FIG. 4 is a circuit diagram showing an asymmetric charge pump according to an exemplary embodiment of the inventive concept. Referring to FIG. 4, an asymmetric charge pump 12a is similar to the charge pump in FIG. 2 except that the third PMOS transistor PM3 in FIG. 2 is removed from a switch circuit 123a and the third NMOS transistor NM3 is added in the switch circuit 123a. The third NMOS transistor NM3 has a drain connected with the first node N1, a source connected with the fourth node N4, and a gate connected to receive an up-bar signal UPB. The third NMOS transistor NM3 may be configured such that a voltage of the first node N1 is maintained at an output voltage VC when the first PMOS transistor PM1 is turned off.

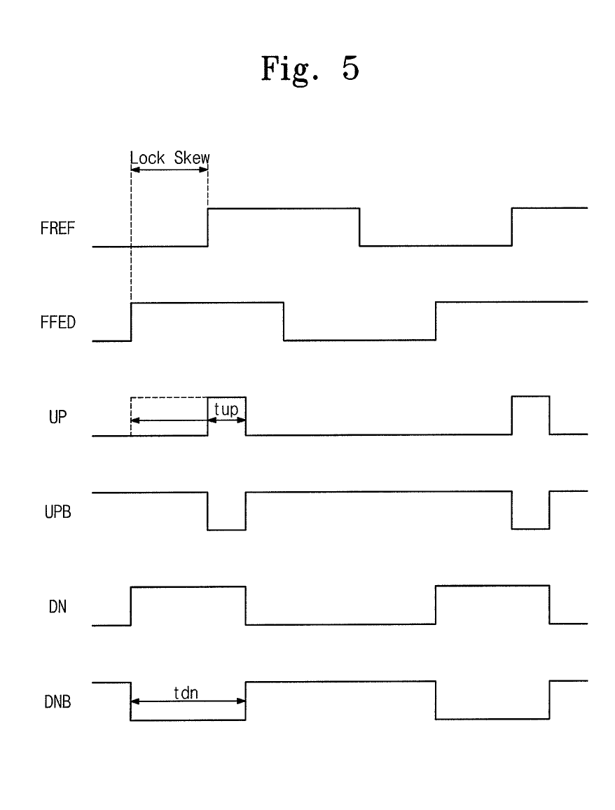

FIG. 5 is a timing diagram for describing how lock skew may be reduced by the asymmetric charge pump illustrated in FIG. 4. Referring to FIG. 5, a reference signal FREF and a feedback signal FFED satisfy the first locking condition and do not satisfy the second locking condition. For example, lock skew arises although a frequency of the reference signal FREF is identical or substantially identical to that of the feedback signal FFED because a time tup is shorter than a time tdn. However, this lock skew may be decreased by increasing the time tup.

Since the first locking condition is satisfied and the time tup is shorter than the time tdn, an outflow amount of down current IDN is less than an inflow amount of up current IUP. Accordingly, the time tup may be increased by reducing an actual inflow time of the up current IUP by controlling the switch circuit 123a such that a voltage of the first node N1 is maintained at the output voltage VC.

Although a turn-on voltage is applied to a gate of the first PMOS transistor PM1, its actual turn-on operation may be performed when a voltage of the first node N1 greater than at least a threshold voltage Vth (e.g., a threshold voltage of a transistor).

An actual turn-on time of the first PMOS transistor PM1 may decrease as the output voltage VC decreases. Accordingly, the time tup for locking of the PLL 10 increases, and a difference between the times tup and tdn decreases. As a result, the lock skew of the PLL decreases.

As described above, the asymmetric charge pumps 12 and 12a according to exemplary embodiments of the inventive concept may be realized to reduce an actual time of down current IDN discharged from a loop filter 13 and to reduce an actual time of up current IUP supplied to the loop filter 13. However, the asymmetric charge pumps of the inventive concept are not limited thereto. For example, an asymmetric charge pump may be realized to control/adjust an actual time of down current IDN discharged from a loop filter 13 and to control/adjust an actual time of up current IUP supplied to the loop filter 13, thereby reducing lock skew.

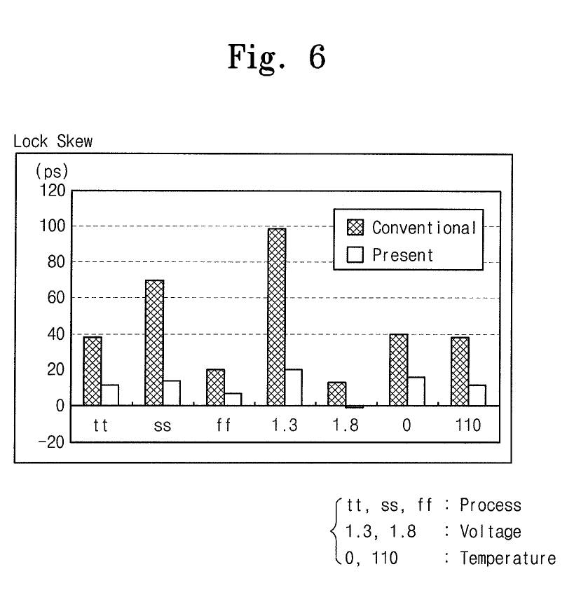

FIG. 6 is a diagram for comparing lock skews of a phase locked loop of exemplary embodiments of the inventive concept and a conventional phase locked loop. Referring to FIG. 6, as compared with a conventional phase locked loop, a phase locked loop according to at least one embodiment of the present invention has a reduced lock skew.

In FIG. 6, a horizontal axis indicates process, voltage, and temperature (PVT) conditions, and a vertical axis indicates a lock skew value of a phase locked loop. In FIG. 6, the first columns are obtained by testing a phase locked loop under the PVT condition of (tt, 1.5V, and 55° C.), and the remaining columns are obtained by testing the phase locked loop with the process, voltage, and temperature being changed one by one. For example, the second columns are obtained by testing the phase locked loop under the PVT condition of (ss, 1.5V, and 55° C.), and the fourth columns are obtained by testing the phase locked loop under the PVT condition of (tt, 1.3V, and 55° C.). The conventional phase locked loop has a maximum lock skew of 99 ps. However, a phase locked loop according to at least one exemplary embodiment of the inventive concept may have a maximum lock skew of 20 ps.

According to at least one exemplary embodiment of the inventive concept, lock skew within a PLL may be reduced by controlling/adjusting a difference between up current IUP and down current IDN according to a variation of an output voltage.

A charge pump or PLL including the charge pump according to at least one exemplary embodiment of the inventive concept may be used in various communication systems and devices. For example, the charge pump or PLL may be used to communicate with a flash memory.

Although exemplary embodiments of the present inventive concept have been described, it is understood that the present inventive concept should not be limited to these exemplary embodiments, and various changes and modifications can be made by one ordinary skilled in the art within the spirit and scope of the disclosure.

What is claimed is:

1. A charge pump comprising:
a current source configured to generate a first current; and
a switch circuit including an output node, connected to the current source, and configured to be switched to provide one of the first current to the output node or discharge a second current from the output node according to a phase difference between a reference signal and a feedback signal,
wherein the switch circuit is further configured to compare a charge supplied to the output node and a charge discharged from the output node and to adjust one of an inflow time of the first current to the output node or an outflow time of the second current from the output node according to the comparison result.

2. The charge pump of claim 1, wherein the switch circuit is configured to enable a constant current to flow through the current source when either the first or second current is absent.

3. The charge pump of claim 1 further comprising:
a first transistor;
a second transistor;
a third transistor;
a first complimentary transistor;
a second complimentary transistor;
a second current source; and
an amplifier,
wherein a first non-gate terminal of the first transistor is connected to the current source and the second transistor, and a second other non-gate terminal of the first transistor is connected to the output node,
wherein a first non-gate terminal of the first complimentary transistor is connected to the output node, and a second other non-gate terminal of the first complimentary transistor is connected to the second current source, the second complimentary transistor, and the third transistor,
wherein a first non-gate terminal of the second transistor is connected to the current source and the first transistor, and a second other non-gate terminal of the second transistor is connected to an output of the amplifier, the second complimentary transistor, and the third transistor, and
wherein a first non-gate terminal of the second complimentary transistor and the third transistor are connected to the output of the amplifier and the second transistor, and a second other non-gate terminal of the second complimentary transistor and the third transistor are connected to the first complimentary transistor and the second current source.

4. The charge pump of claim 1, further comprising a power supply supplying a power supply voltage to the current source.

5. The charge pump of claim 3, wherein the second current source is connected at one end to the first complimentary transistor, the second complimentary transistor, and the third transistor, and the second current source is connected at another end to a ground.

6. The charge pump of claim 3, wherein one input of the amplifier is connected to the output of the amplifier and another input of the amplifier is connected to the output node.

7. The charge pump of claim 3 wherein the first through third transistors are PMOS transistors and the first and second complimentary transistors are NMOS transistors.

8. The charge pump of claim 1 further comprising:
a first transistor;
a second transistor;
a third transistor;
a first complimentary transistor;
a second complimentary transistor;
a second current source; and
an amplifier,
wherein a first non-gate terminal of the first transistor is connected to the current source, the second transistor, and the third complimentary transistor, and a second other non-gate terminal of the second transistor is connected to the output node,
wherein a first non-gate terminal of the first complimentary transistor is connected to the output node, and a second other non-gate terminal of the first complimentary transistor is connected to the second current source and the second complimentary transistor,
wherein a first non-gate terminal of the second transistor and the third complimentary transistor are connected to the current source and the first transistor, and a second other non-gate terminal of the second transistor and the third complimentary transistor are connected to an output of the amplifier and the second complimentary transistor, and
wherein a first non-gate terminal of the second complimentary transistor is connected to the output of the amplifier and the second transistor, and a second other non-gate terminal of the second complimentary transistor is connected to the first complimentary transistor and the second current source.

9. A charge pump comprising:
a first current source connected between a power supply voltage and a first node and configured to generate a first current;
a first switch connected between the first node and a second node and configured to operate in response to a first signal generated according to a phase difference between a reference signal and a feedback signal;
a second current source connected between a ground voltage and a third node and configured to generate a second current; and
a second switch connected between the second node and the third node and to operate in response to a second signal generated according to a phase difference between the reference signal and the feedback signal,
wherein the first and second switches are configured to compare a charge supplied to the second node and a charge discharged from the second node and to adjust one of an inflow time of a current flowing to the second node or an outflow time of a current flowing from the second node according to the comparison result.

10. The charge pump of claim 9, wherein when the first switch is on, the second node is set to a voltage of the first node.

11. The charge pump of claim 9, wherein when the first switch is off, the second node is set to a voltage of the third node.

12. The charge pump of claim 9, wherein the first switch is configured to force a constant current to flow through the first current source when no current flows to the second node, and the second switch is configured to force a constant current to flow through the second current source when no current is discharged from the second node.

13. The charge pump of claim 12, wherein the first switch comprises:
a first PMOS transistor having a source connected with the first node, a drain connected with the second node, and a gate connected to receive an inverted version of the first signal;
a second PMOS transistor having a source connected with the first node,
a drain connected with a fourth node supplied with a voltage of the second node, and a gate connected to receive the first signal; and
a third PMOS transistor having a source connected with the fourth node, a drain connected with the third node, and a gate connected to receive the second signal and,
wherein the second switch comprises:
a first NMOS transistor having a drain connected with the second node, a source connected with the third node, and a gate connected to receive the second signal; and
a second NMOS transistor having a drain connected with the fourth node, a source connected with the third node, and a gate connected to receive an inverted version of the second signal.

14. The charge pump of claim 12, wherein the first switch comprises:
a first PMOS transistor having a source connected with the first node, a drain connected with the second node, and a gate connected to receive an inverted version of the first signal; and
a second PMOS transistor having a source connected with the first node, a drain connected with a fourth node supplied with a voltage of the second node, and a gate connected to receive the first signal and,
wherein the second switch comprises:
a first NMOS transistor having a drain connected with the second node, a source connected with the third node, and a gate connected to receive the second signal;
a second NMOS transistor having a drain connected with the fourth node, a source connected with the third node, and a gate connected to receive an inverted version of the second signal; and
a third NMOS transistor having a drain connected with the first node, a source connected with the fourth node, and a gate connected to receive the third signal.

15. The charge pump of claim 9, further comprising an amplifier having a first input terminal, a second other input terminal, and an output terminal, wherein the first input terminal is connected to the second node, and the second other input terminal is connected to the output terminal.

16. A phase locked loop comprising:
a phase detector configured to detect a phase difference between a reference signal and an output signal and to generate a first signal and a second signal according to the detection result;
a charge pump configured to supply a first current to an output node in response to the first signal and to discharge a second current from the output node in response to the second signal;
a loop filter connected to the output node and configured to generate a control voltage according to one of the first current or the second current and to maintain the control voltage; and
a voltage controlled oscillator configured to generate the output signal having a frequency corresponding to the control voltage,
wherein the charge pump is configured to control one of an inflow time of the first current to the loop filter or an outflow time of the second current from the loop filter when the control voltage is maintained constantly.

17. The phase locked loop of claim 16, wherein the charge pump comprises:
a current source; and
a switch circuit including the output node, connected to the current source, and configured to operate in response to the first and second signals.

18. The phase locked loop of claim 17, wherein the switch circuit comprises:
a first transistor;
a second transistor;
a third transistor;
a first complimentary transistor;
a second complimentary transistor;
a second current source; and
an amplifier.

19. The phase locked loop of claim 18, wherein a first non-gate terminal of the first transistor is connected to the current source and the second transistor, and a second other non-gate terminal of the first transistor is connected to the output node,
wherein a first non-gate terminal of the first complimentary transistor is connected to the output node, and a second other non-gate terminal of the first complimentary transistor is connected to the second current source, the second complimentary transistor, and the third transistor,
wherein a first non-gate terminal of the second transistor is connected to the current source and the first transistor, and a second other non-gate terminal of the second transistor is connected to an output of the amplifier, the second complimentary transistor, and the third transistor, and
wherein a first non-gate terminal of the second complimentary transistor and the third transistor are connected to the output of the amplifier and the second transistor, and a second other non-gate terminal of the second complimentary transistor and the third transistor are connected to the first complimentary transistor and the second current source.

20. The phase locked loop of claim 18, wherein a first non-gate terminal of the first transistor is connected to the current source, the second transistor, and the third complimentary transistor, and a second other non-gate terminal of the second transistor is connected to the output node,
wherein a first non-gate terminal of the first complimentary transistor is connected to the output node, and a second other non-gate terminal of the first complimentary transistor is connected to the second current source and the second complimentary transistor,
wherein a first non-gate terminal of the second transistor and the third complimentary transistor are connected to the current source and the first transistor, and a second other non-gate terminal of the second transistor and the third complimentary transistor are connected to an output of the amplifier and the second complimentary transistor, and
wherein a first non-gate terminal of the second complimentary transistor is connected to the output of the amplifier and the second transistor, and a second other non-gate terminal of the second complimentary transistor is connected to the first complimentary transistor and the second current source.
